(19) United States
(12) Patent Application Publication
(10) Pub. No.: US 2025/0318042 A1
(43) Pub. Date: Oct. 9, 2025

(54) HEAT DISSIPATION MODULE FOR CIRCUIT BOARD

(71) Applicant: V-COLOR TECHNOLOGY INC., NEW TAIPEI CITY (TW)

(72) Inventor: TIEN SHUN HO, NEW TAIPEI CITY (TW)

(21) Appl. No.: 18/668,549

(22) Filed: May 20, 2024

(30) Foreign Application Priority Data
Apr. 9, 2024 (TW) 113203459

(51) Int. Cl. H05K 1/02; H01L 23/367; H01L 23/373

(52) U.S. Cl. CPC H05K 1/0203; H01L 23/3675; H01L 23/3677; H01L 23/3736; H05K 2201/064; H05K 2201/10159

(57) ABSTRACT

Disclosed is a heat dissipation module for a circuit board, including: a circuit board and a heat sink, wherein the circuit board is provided with at least one chip as the main heat source. The heat sink is disposed correspondingly to the outer surface of the chip to conduct heat for dissipation. By targeting the main heat source for heat dissipation, the size of the heat dissipation module is reduced. When a plurality of circuit boards are used side by side, the raised heat sinks can also push apart the adjacent circuit boards so as to form air flow channels, maintaining the gap between the circuit boards so that air can flow through and take away heat.

### CROSS-REFERENCE TO RELATED APPLICATION

This application claims the priority of Taiwanese patent application No. 113203459, filed on Apr. 9, 2024, which is incorporated herewith by reference.

### BACKGROUND OF THE INVENTION

### 1. Field of the Invention

The present invention relates generally to a device used in the field of circuit board heat dissipation, and more particularly to a heat dissipation module for a memory circuit board to be installed at locations with small spacing.

### 2. The Prior Arts

In recent years, with the development of chip technology, chip circuit manufacturing processes have become more and more precise, and compared with the past, the chips and resulted circuits are smaller in size but have higher work efficiency. However, high performance is accompanied by high power consumption. As power consumption increases, heat generation also rises sharply. When the temperature of the electronic components in the chip circuit continues to rise, the stability will suffer. If the heat is not removed immediately and the temperature continues to increase, it may even affect performance or cause component burnout. Because traditional memory does not generate high heat, most of the memory chips simply rely on the natural convection heat dissipation of the component itself. As technology progresses and the size of memory chips decreases, the performance of memory chips increases, and the amount of heat generated per unit area increases geometrically. Traditional natural heat dissipation is no longer sufficient. Therefore, external heat dissipation modules began to appear in memory circuit board, providing solutions to high heat dissipation.

The heat dissipation module of the conventional memory is a full-coverage design. FIG. 1 shows a schematic view of a disassembled conventional heat dissipation module. As shown in FIG. 1, the heat dissipation module is divided into a first heat sink A1 and a second heat sink A2. By assembling the first heat sink A1 and the second heat sink A2, the heat dissipation module covers the entire memory. In addition, memory dies or chips 23 are bonded to the inner sides of the first heat sink A1 and the second heat sink A2 to conduct the generated heat to the heat dissipation module. With the good thermal conductivity of the heat dissipation module to dissipate heat, increase the heat dissipation effect can be improved by increasing heat dissipation area. However, after the conventional heat dissipation module is installed on the memory, the arrangement to cover all the electronic components will inevitably increase the total thickness of the single memory. In the older PC or server hardware architecture design, the number of memory slots was small and the space was large enough to accommodate thicker memory. Today's personal computers or server hosts have begun to increase the number of slots in order to increase computing efficiency and functions; especially for server hosts or workstation hosts, most users will install up to dozens of memories at the same time. As the assembly space shrinks, memory size must be limited. In addition, in order to increase performance, some users use overdriving technology to increase the voltage to increase the operating clock rate of the memory, which means increasing the frequency of the transistor to increase performance, resulting in higher heat generation. Even if the conventional heat dissipation modules can be used, when a plurality of sets of memory are installed on the motherboard, the thickened memory cannot provide enough gaps for air to circulate between the memories, which will also affect the heat dissipation area of the memory and reduce the heat dissipation effect.

Taiwan Patent No. M608745, M401149 and M493085 disclose various conventional heat dissipation module structures.

In view of the shortcomings of the full-coverage design of conventional memory heat dissipation modules, which have taken up too much space and resulted in ineffective heat dissipation with multiple sets of memories installed side by side, it is imperative to address the above issues.

### SUMMARY OF THE INVENTION

A primary objective of the present invention is to provide a heat dissipation module that covers the main heat sources, such as: Power Management Integrated circuit (PMIC), Register Clock Driver (RCD), so as to reduce the size of the heat dissipation module, reduce the thickness of the heat dissipation module, and increase the heat dissipation effect, applicable to devices with a plurality of memory sets installed side by side.

In order to solve the aforementioned problems, the present invention provides a heat dissipation module for circuit board, which includes a circuit board and a heat sink; the circuit board is provided with at least one chip as a main heat source, and the heat sink is correspondingly arranged on the surface of the chip, wherein the heat sink has good thermal conductivity to absorb and dissipate heat into the air.

Preferably, the heat sink has a groove, and the chip can be placed in the groove when connecting to the heat sink to improve the connection stability of the heat sink.

Preferably, the heat sink is a flat piece with two opposite sides, one side of which is connected to a surface of the chip, and can be adhered to the surface of the chip using thermal paste or thermal conductive glue.

Preferably, the heat sink has patterned trench, and the outer surface of the heat sink has grid-type, rhombus-type, twill-type or cross-type trenches to increase the heat dissipation surface area and avoid close contact between the heat sinks of adjacent memory devices.

Preferably, the heat sink has fins, and the fins are formed on the outer surface of the heat sink to increase the heat dissipation surface area.

Preferably, when a plurality of memories is used side by side, the heat sink pushes away to separate the adjacent memories so as to form an air flow channel to maintain the air circulation between the adjacent memories and maintain the heat dissipation effect.

Preferably, the chip is a register clock driver (RCD) for processing signals from a controller.

Preferably, the chip is a Power Management Integrated Circuit (PMIC) used to assist in allocating the power required by each module of the memory.

In summary, the present invention utilizes the design of the heat sink to cover the main heat source to reduce the size of the heat dissipation module. And, when the memory circuit boards are installed side by side, the protruding thickness of the heat dissipation module can push away the adjacent circuit boards, preventing the circuit board components from being in close contact, thereby increasing the gap and improving the heat dissipation effect.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is an exploded schematic view of a conventional heat dissipation module;

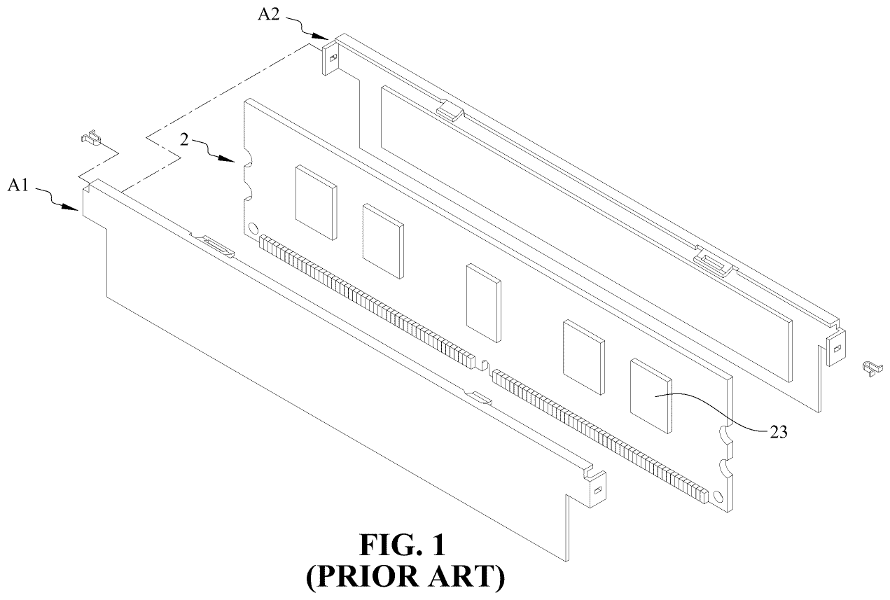

FIG. 2 is an exploded schematic view of the present invention;

FIG. 3 is a schematic assembled view of the present invention;

FIG. 4 is a schematic view of the side-by-side use of a plurality of memory sets equipped with heat dissipation modules according to the embodiment of the present invention;

FIG. 5 is a cross-sectional view along the line B-B of the first embodiment of the present invention shown in FIG. 3;

FIG. 6 is a cross-sectional view along the line B-B of the second embodiment of the present invention shown in FIG. 3;

FIG. 7 is a schematic diagram of the third embodiment of the present invention; and

FIG. 8 is a schematic three-dimensional view of the fourth embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

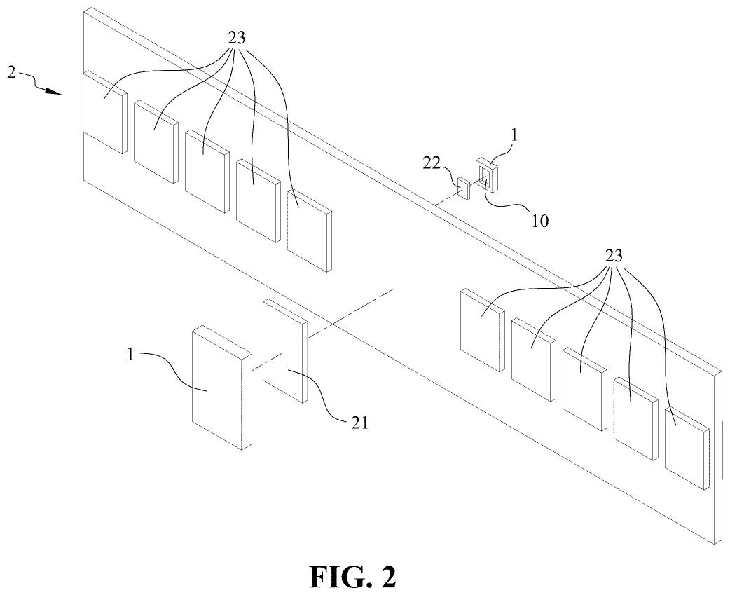

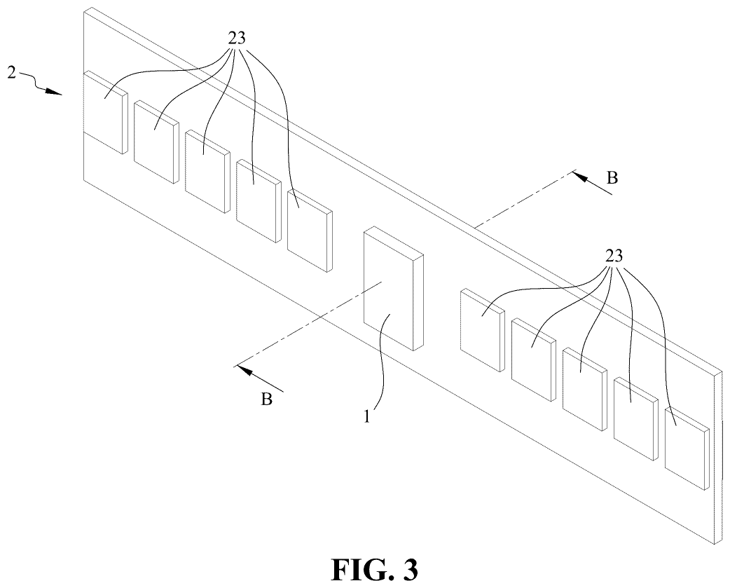

FIGS. 2 to 8 are schematic views of the heat dissipation module of the circuit board of the present invention. FIG. 2 is an exploded view of the present invention and FIG. 3 is a schematic view of the assembly of the present invention embodiment. The heat dissipation module for circuit board of the present invention is shown in FIGS. 2-8, including a heat sink 1 and a circuit board 2. The circuit board 2 has a first chip 21, a second chip 22, and a plurality of memory chips 23. The heat sink is connected to the outer surfaces of the first chip 21 and the second chip 22 to absorb and dissipate the heat generated by the first chip 21 and the second chip 22 into the air.

Furthermore, the first chip 21 and the second chip 22 are the main heat sources of the circuit board 2 and are responsible for controlling the power supply of the plurality of memory chips 23 and the circuit board 2. The present invention only connects the heat sink 1 correspondingly to the main heat source of the circuit board 2 to reduce the size of the heat dissipation module. Moreover, compared to bare memory strips without a heat dissipation module, the heat dissipation effect can be improved by 30% to 40%.

Specifically, the circuit board 2 is provided with at least one chip as the main heat source, and the heat sink 1 is correspondingly provided on the surface of the chip, and the heat of the chip is absorbed by the good thermal conductivity of the heat sink 1. Then, the heat is taken away by the air flowing through the heat sink.

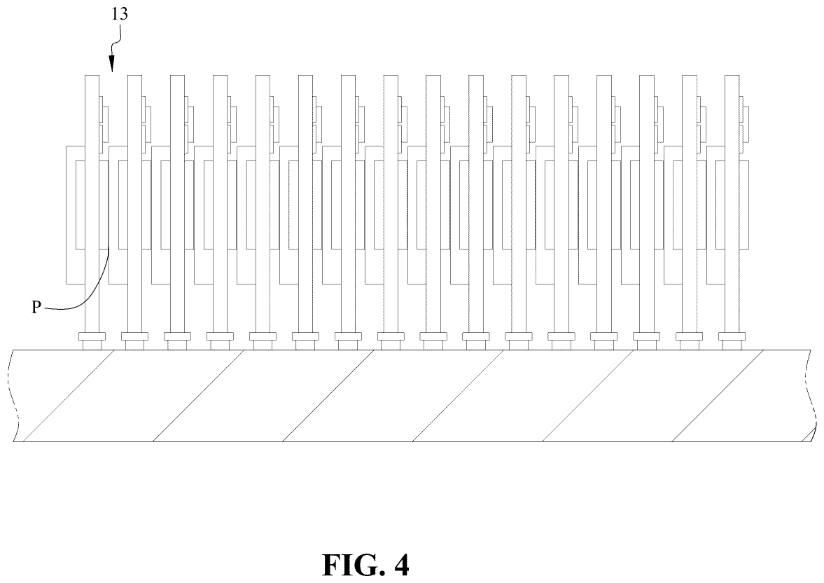

As shown in the schematic view of the side-by-side use of a plurality of memory sets equipped with heat dissipation modules according to the present invention in FIG. 4, the plurality of memory circuit boards 2 are used side by side and the heat sink 1 is installed on the surface of the chip. When the distance between adjacent circuit boards 2 is very small, the end surface P of the heat sink 1 can be placed against the adjacent circuit boards 2 to prevent the circuit boards from touching, so as to maintain an air flow channel 13 for air to flow through for heat dissipation.

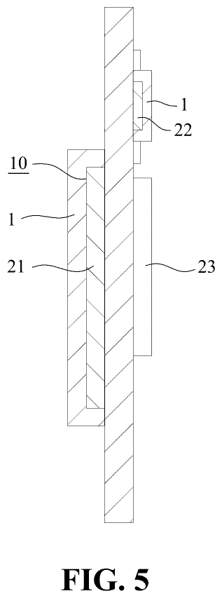

FIG. 5 is a schematic cross-sectional view along the line B-B of the first embodiment of the present invention shown in FIG. 3, wherein the heat sink 1 has a groove 10. Moreover, the first chip 21 and the second chip 22 can be placed in corresponding heat sinks 1 so that the heat sinks 1 completely cover the outer surfaces of the first chip 21 and the second chip 22 to increase the connection stability.

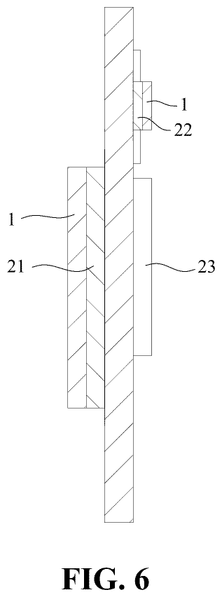

FIG. 6 is a schematic cross-sectional view along the line B-B of the second embodiment of the present invention shown in FIG. 3, wherein the heat sink 1 can be a flat sheet body with two opposite sides, with one side connected to surfaces of the first chip 21 and the second chip 22, attached by thermal conductive glue or heat dissipation paste.

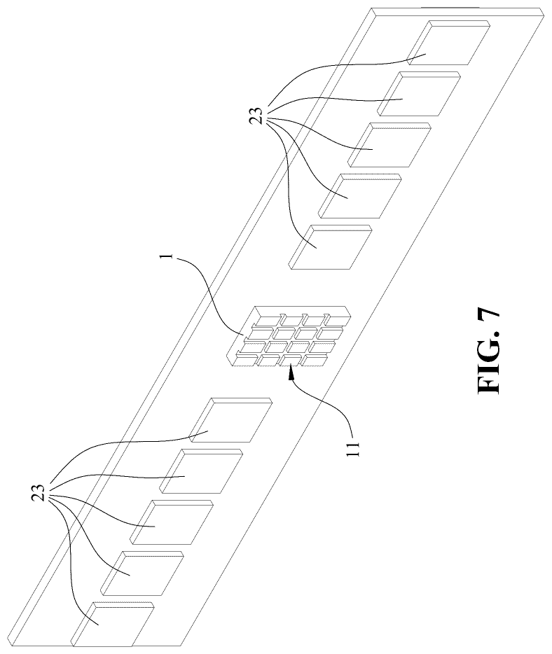

FIG. 7 shows a schematic view of the third embodiment of the present invention, wherein the heat sink 1 has patterned trenches 11 to increase the heat dissipation surface area.

Preferably, the pattern of the trenches 11 can be a grid type, a rhombus type, a twill type or a cross type.

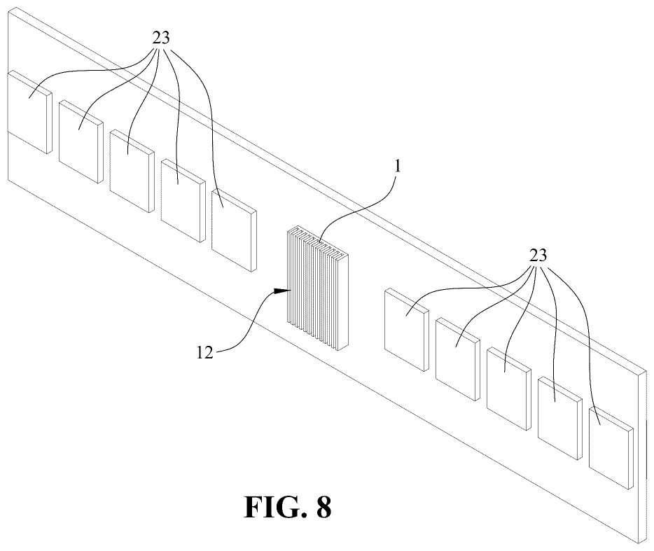

FIG. 8 shows a perspective view of the fourth embodiment of the present invention, wherein the heat sink has fins 12.

Preferably, the heat sink 1 is made of metal or copper alloy.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A heat dissipation module for a circuit board, comprising:
a circuit board, disposed with at least one chip as a main heat source; and
a heat sink, correspondingly disposed on a surface of the chip.

2. The heat dissipation module according to claim 1, wherein the heat sink has a groove, and the chip is placed in the groove.

3. The heat dissipation module according to claim 1, wherein the heat sink is a sheet having two opposite sides of flat surface, with one side connected to the surface of the chip.

4. The heat dissipation module according to claim 1, wherein the heat sink is disposed with at least a trench.

5. The heat dissipation module according to claim 4, wherein the outer surface of the heat sink has grid-type, rhombus-type, twill-type or cross-type trenches.

6. The heat dissipation module according to claim 1, wherein the heat sink is formed with at least one fin.

7. The heat dissipation module according to claim 1, wherein the heat sink is made of metal or copper alloy.
